(19) United States
(12) Patent Application Publication
(10) Pub. No.: US 2008/0054957 A1
(43) Pub. Date: Mar. 6, 2008

(54) Skew Correction Apparatus

(76) Inventors: Noriaki Takeda, Hyogo (JP); Tohru Iwata, Osaka (JP)

Correspondence Address: MCDERMOTT WILL & EMERY LLP, 600 13TH STREET, NW, WASHINGTON, DC, 20005-3096, US

(21) Appl. No.: 11/587,855

(22) PCT Filed: Dec. 8, 2004
(86) PCT No.: PCT/JP04/18255

§ 371 Date: Oct. 27, 2006

(30) Foreign Application Priority Data
May 26, 2004 (JP) 2004-156338

(51) Int. Cl. H03L 7/06; H03K 3/037; H03K 5/00; H03K 5/13

(52) U.S. Cl. 327/143; 327/158

(57) ABSTRACT

A skew correction apparatus is composed of a variable delay line 200 for generating a delayed clock signal DCLK by delaying a clock signal CLK by a variable delay amount DT, a phase comparator 10 for comparing a phase of the delayed clock signal DCLK with transition of rising of a data signal DAT, a voltage holding means 6 for holding a voltage Vcntl for controlling the delay amount DT of the variable delay line 200, a charging/discharging means 30 for charging or discharging the voltage holding means 6, depending on a comparison result of the phase comparator 10, a charging means 40 for setting the voltage Vcntl of the voltage holding means 6 during initial setting, and a control circuit 500 for controlling the charging means 40.

### TECHNICAL FIELD

The present invention relates to a skew correction apparatus for correcting a skew of a data signal with respect to a clock signal.

### BACKGROUND ART

In high-speed data communication systems, data reception elements require that a data signal is set up a predetermined time (called a setup time) before a clock edge of a clock signal. Also, even assuming that a data signal is generated in a manner which allows a predetermined setup time to be secured with respect to a clock signal, if the clock signal and the data signal have different propagation delay times, a skew (“deviation” in time) occurs between the clock signal and the data signal. As a result, a problem arises with a phase relationship between a clock signal and a data signal which are received by the data reception element. Particularly, as the speed of communication is increased, the “deviation” is more likely to cause reception of erroneous data.

To solve such a problem, conventional skew correction apparatuses comprise a transition detector for detecting transition of a data signal and supplying a pulse signal indicating the detection, a variable delay line for generating a delayed data signal by delaying a data signal by a variable delay amount, and a phase comparator for comparing transition of the delayed data signal with a phase of a clock signal under a condition that the pulse signal is supplied, and controls a delay amount of the variable delay line so that the transition of the delayed data signal and a clock edge of the clock signal have substantially the same phase. According to this conventional technique, it is possible to correct a skew between the clock edge and the data signal. Also, it is possible to correct the skew, depending on a change in an environment, such as a temperature change or the like, in a normal operation mode (see, for example, Patent Document 1).

Patent Document 1: JP No. 11-168365 A (particularly FIG. 1)

Patent Document 2: U.S. Pat. No. 6,759,882

### DISCLOSURE OF THE INVENTION

### Problems to be Solved by the Invention

Since there is jitter (“fluctuation” of a clock edge) in clock signals and data signals, a skew invariably changes. The jitter is composed of a plurality of frequency components. To accurately receive data, typically, it is preferable that fast frequency jitter be removed by filtering and an operation be performed, following slow frequency jitter.

To perform an operation, following jitter, a margin for correcting a skew caused by jitter in addition to a skew which is conventionally to be corrected, needs to be set within a variable delay range of the variable delay line. However, in conventional skew correction apparatuses, such a margin is not set within the variable delay range of the variable delay line. Also, in conventional skew correction apparatuses, particularly when an operation is performed while a delay is locked in the vicinity of an upper or lower limit of the variable delay range of the variable delay line, the delay amount of the variable delay line cannot be increased or decreased, following jitter, so that error is likely to occur in data reception.

In view of the above description, an object of the present invention is to provide a skew correction apparatus capable of achieving data reception highly resistant to jitter.

### Solution to the Problems

A basic concept of the present invention for achieving the above-described object is that, during initial setting, a control voltage of a variable delay line is set so that a phase comparison operation is performed from an intermediate point within a variable range of a delay amount of the variable delay line. In this case, the variable range of the delay amount of the variable delay line is caused to have, in each of a direction in which a delay is increased and a direction in which a delay is decreased, an addition of a delay amount of ½ or more of a clock cycle and a delay amount required for correcting a skew due to jitter. Thereby, a skew previously occurring at the time of start of a phase comparison operation can be corrected by a delay amount within a range of ±½ cycle, and a skew occurring due to jitter can be followed and corrected. Also, when the delay amount of the variable delay line reaches an upper or lower limit of the variable range, the control voltage of the variable delay line is reset, and initial setting and thereafter are performed again.

Specifically, a first skew correction apparatus according to the present invention is a skew correction apparatus for correcting a skew of a data signal with respect to a clock signal, comprising a variable delay line for generating a delayed clock signal by delaying the clock signal by a variable delay amount, a phase comparator for comparing transition of the data signal with a phase of the delayed clock signal, a voltage holding means for adjusting a delay amount of the variable delay line, depending on a held voltage, a charging/discharging means for changing the voltage of the voltage holding means, depending on a comparison result of the phase comparator, a charging means for setting an initial value of the voltage of the voltage holding means at start of a phase comparison operation, as an initial setting, and a control circuit for controlling the charging means so that a phase comparison operation is started in a state that the variable delay line delays the clock signal by a delay amount which is intermediate within a delay adjustable range, to determine the initial value as the initial setting.

Also, a second skew correction apparatus according to the present invention is A skew correction apparatus for correcting a skew of a data signal with respect to a clock signal, comprising a variable delay line for generating a delayed data signal by delaying the data signal by a variable delay amount, a phase comparator for comparing transition of the delayed data signal with a phase of the clock signal, a voltage holding means for adjusting a delay amount of the variable delay line, depending on a held voltage, a charging/discharging means for changing the voltage of the voltage holding means, depending on a comparison result of the phase comparator, a charging means for setting an initial value of the voltage of the voltage holding means at start of a phase comparison operation, as an initial setting, and a control circuit for controlling the charging means so that a phase comparison operation is started in a state that the variable delay line delays the data signal by a delay amount which is intermediate within a delay adjustable range, to determine the initial value as the initial setting.

In the first or second skew correction apparatus, preferably, at start of phase comparison, the variable delay line has a variable delay range of half of a clock cycle (½ cycle) or more in each of a direction in which a delay amount is decreased and a direction in which a delay amount is increased. Specifically, preferably, at start of phase comparison, the variable delay line has a variable delay range of no less than a sum of the ½ cycle and a margin which is set in view of an influence of fluctuation due to jitter, in each of a direction in which a delay amount is decreased and a direction in which a delay amount is increased.

In this case, the control circuit may comprise a clock detector for detecting transition of output of the variable delay line and outputting a clock detection signal indicating the transition, and may cause a phase comparison operation to start under a condition that the clock detector has detected the transition. Also, during the initial setting, the control circuit may set the voltage of the voltage holding means to be a predetermined voltage in one charging operation by the charging means.

When the control circuit comprises a clock detector, during the initial setting, the control circuit may control the charging means so that the initial value is determined under conditions that the voltage of the voltage holding means is increased at a constant increasing rate and the clock detection signal is being output. In this case, the control circuit may control the charging means so that the initial value is determined by further applying a predetermined voltage to the voltage holding means after the clock detection signal is output.

Also, when the control circuit comprises a clock detector, during the initial setting, the control circuit may control the charging means so that the voltage of the voltage holding means is increased in a stepwise manner in units of a predetermined voltage, and the initial value is determined by repeatedly applying the predetermined voltage to the voltage holding means the number of times corresponding to a predetermined number of stages from a stage at which the clock detection signal has been output after confirming output of the clock detection signal for each stage.

Also, when the control circuit comprises a clock detector, when the output of the clock detection signal from the clock detector is stopped, the control circuit may reset the voltage holding means and performs the initial setting and thereafter again.

In the first or second skew correction apparatus, the control circuit may start a phase comparison operation a predetermined time after end of the initial setting.

In the first or second skew correction apparatus, preferably, the control circuit, when the delay amount of the variable delay line reaches an upper or lower limit of the variable range, resets the voltage holding means and performs the initial setting and thereafter again.

In the first or second skew correction apparatus, preferably, the control circuit controls the charging means so that the initial value is changed, depending on a frequency of the clock signal. Also, in this case, preferably, the control circuit comprises a frequency detecting circuit for detecting the frequency of the clock signal, and depending on a detection result of the frequency detecting circuit, controls the charging means so that the initial value is changed.

### EFFECT OF THE INVENTION

According to the present invention, the phase comparison operation is started from an intermediate point within the variable range of the delay amount of the variable delay line, thereby making it possible to perform conventional skew correction no matter whether a phase is delayed or advanced, and perform an operation, following fluctuation due to jitter. In addition, when the delay amount of the variable delay line reaches the upper or lower limit of the variable range, resetting is performed and initial setting and thereafter are performed again, thereby making it possible to prevent reception of erroneous data.

### BRIEF DESCRIPTION OF THE DRAWINGS

FIG. 1 is a block diagram illustrating an exemplary configuration of a skew correction apparatus according to an embodiment of the present invention.

FIG. 2 is a block diagram illustrating an exemplary internal configuration of a charging/discharging means of FIG. 1.

FIG. 3 is a block diagram illustrating an exemplary internal configuration of a variable delay line of FIG. 1.

FIG. 4 is a block diagram illustrating an exemplary internal configuration of a delay cell of FIG. 3.

FIG. 5 is a block diagram illustrating an exemplary internal configuration of a bias generating circuit of FIG. 3.

FIG. 6 is a graph illustrating a relationship between a delay amount of the variable delay line of FIG. 1 and a control voltage.

FIG. 7 is a block diagram illustrating an exemplary internal configuration of a control circuit of FIG. 1.

FIG. 8 is a block diagram illustrating an exemplary internal configuration of a charging means of FIG. 1.

FIG. 9 is a block diagram illustrating an exemplary internal configuration of a clock detecting circuit of FIG. 7.

FIG. 10 is a timing diagram of initial setting by the charging means of FIG. 8.

FIG. 11 is a block diagram illustrating an exemplary internal configuration of a reset control circuit of FIG. 7.

FIG. 12 is a block diagram illustrating an exemplary internal configuration of a frequency detecting circuit of FIG. 7.

### DESCRIPTION OF THE REFERENCE CHARACTERS

6 voltage holding means
7 switch
10 phase comparator
30 charging/discharging means
31 current source
32 switch
33 switch
34 current source
40 charging means
41 switch
42 resistance
43 switch
200 variable delay line
210 delay line
211 transistor
212 transistor
213 transistor
214 transistor
215 transistor
240 bias generating circuit
241 transistor
242 transistor
243 transistor
244 transistor
500 control circuit
510 clock detecting circuit
511 clock detecting circuit
512 frequency divider
514 D latch
515 delaying means
520 frequency detecting circuit
521 pulse generating circuit
522A inverter chain
522B EXOR gate
523 capacitance
524 resistance
525a comparator
525b comparator
526 transistor
527a switch
527b switch
528a current source
528b current source
528c current source
529 integrator
530 shift register
540 reset control circuit
541 comparator
542 pulse generating circuit
543 pulse generating circuit
5440R gate
545 inverter chain
546 AND gate
547 inverter chain
548 AND gate

### BEST MODE FOR CARRYING OUT THE INVENTION

Hereinafter, a skew correction apparatus according to an embodiment of the present invention will be described with reference to the accompanying drawings.

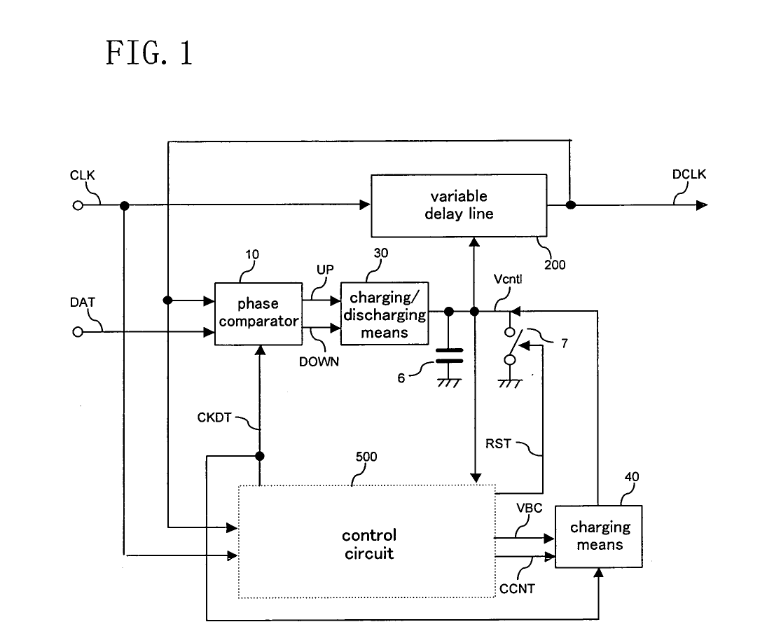

FIG. 1 illustrates an exemplary configuration of a skew correction apparatus of this embodiment. The skew correction apparatus of FIG. 1 is for correcting a skew of a clock signal CLK with respect to a data signal DAT (in other words, a skew of the data signal DAT with respect to the clock signal CLK). The skew correction apparatus comprises: a variable delay line 200 for generating a delayed clock signal DCLK by delaying the clock signal CLK by a variable delay amount DT; a phase comparator 10 for comparing a phase of the delayed clock-signal DCLK with transition of rising of the data signal DAT; a voltage holding means 6 for holding a voltage Vcntl for controlling the delay amount DT of the variable delay line 200; a charging/discharging means 30 for charging or discharging the voltage holding means 6 (i.e., changing a voltage of the voltage holding means 6), depending on a comparison result of the phase comparator 10; a charging means 40 for setting an initial value of the voltage Vcntl of the voltage holding means 6 during initial setting; a switch 7 for resetting the voltage of the voltage holding means 6; and a control circuit 500 for performing, for example, a control of the charging means 40.

The phase comparator 10, when a rising edge of the delayed clock signal DCLK is advanced more than transition of rising of the data signal DAT, supplies a DOWN signal to the charging/discharging means 30 so as to increase the delay amount DT of the variable delay line 200, thereby discharging the voltage holding means 6 to decrease the control voltage Vcntl. On the other hand, when the rising edge of the delayed clock signal DCLK is delayed from the transition of rising of the data signal DAT, the phase comparator 10 supplies an UP signal to the charging/discharging means 30 so as to decrease the delay amount DT of the variable delay line 200, thereby charging the voltage holding means 6 to increase the control voltage Vcntl. As described above, the phase comparator 10 controls the delay amount DT of the variable delay line 200 via the charging/discharging means 30 so that the transition of rising of the data signal DAT has substantially the same phase as that of the rising edge of the delayed clock signal DCLK. Note that, for example, a Hogge's phase comparator or the like can be employed as the phase comparator 10 of FIG. 1.

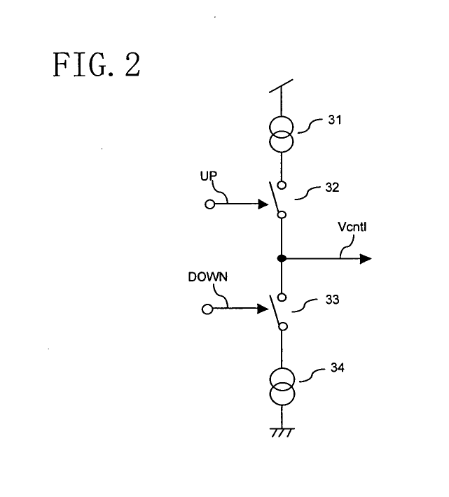

FIG. 2 illustrates an exemplary internal configuration of the charging/discharging means 30 of FIG. 1. As illustrated in FIG. 2, the charging/discharging means 30 is composed of: a current source (transformer) 31 connected to a power supply; a switch 32 connected between the current source 31 and the control voltage Vcntl; a current source 34 connected to the ground; and a switch 33 connected between the current source 34 and the control voltage Vcntl. When the UP signal is supplied from the phase comparator 10 to the charging/discharging means 30, the switch 32 is turned ON, so that the voltage holding means 6 connected to the control voltage Vcntl is charged, whereby the control voltage Vcntl is increased. When the DOWN signal is supplied from the phase comparator 10 to the charging/discharging means 30, the switch 33 is turned ON, so that the voltage holding means 6 connected to the control voltage Vcntl is discharged, whereby the control voltage Vcntl is decreased.

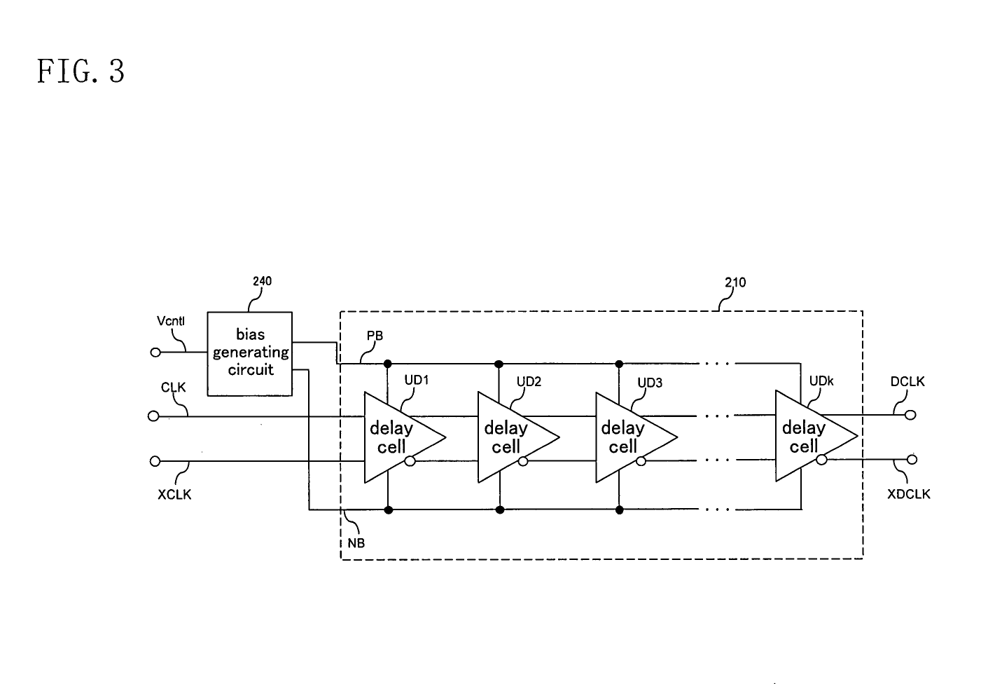

FIG. 3 illustrates an exemplary internal configuration of the variable delay line 200 of FIG. 1. As illustrated in FIG. 3, the variable delay line 200 is composed of an n-stage (n is an integer) delay line 210 and a bias generating circuit 240. The delay line 210 is composed of n delay cells UDk (k=1 to n). In the variable delay line 200, a first bias signal PB and a second bias signal NB are generated by the bias generating circuit 240, depending on the control voltage Vcntl. The clock signal CLK and a signal XCLK having a phase reverse to that of the clock signal CLK are delayed by the delay line 210, and the delayed clock signal DCLK and a signal XDCLK having a phase reversed to that of the delayed clock signal DCLK, each of which is delayed by the delay amount DT, are generated. Note that, in FIG. 1, the reversed-phase signal XCLK and the reversed-phase signal XDCLK are not illustrated.

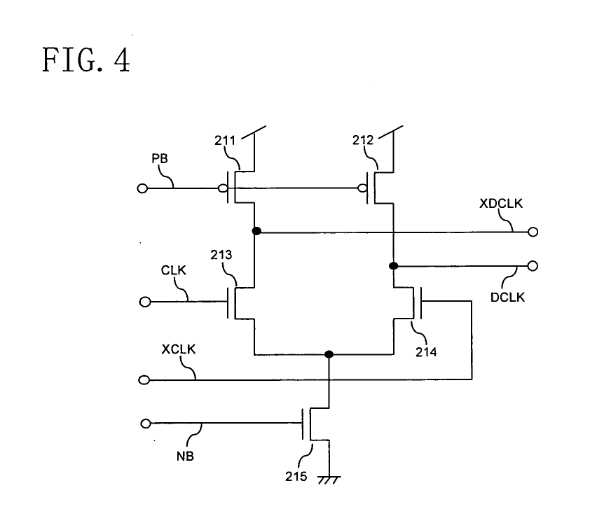

FIG. 4 illustrates an exemplary internal configuration of the delay cell UDk of FIG. 3. As illustrated in FIG. 4, the delay cell UDk is composed of: a transistor 211 which has a source connected to the power supply, a gate connected to the bias signal PB, and a drain connected to the reversed-phase signal XDCLK; a source transistor 212 which has a source connected to the power supply, a gate connected to the bias signal PB, and a drain connected to the delayed clock signal DCLK; a transistor 213 which has a drain connected to the reversed-phase signal XDCLK and a gate connected to the clock signal CLK; a transistor 214 which has a drain connected to the delayed clock signal DCLK and a gate connected to the reversed-phase signal XCLK; and a transistor 215 which has a drain connected to the sources of the transistors 213 and 214 and a gate connected to the bias signal NB, and a source connected to the ground.

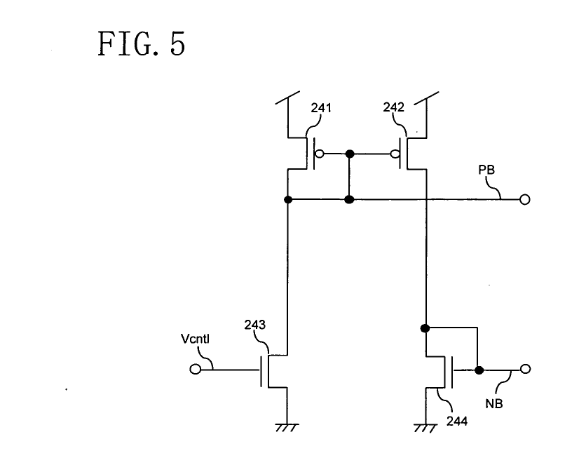

FIG. 5 illustrates an exemplary internal configuration of the bias generating circuit 240 of FIG. 3. As illustrated in FIG. 5, the bias generating circuit 240 is composed of: a transistor 241 which has a source connected to the power supply, and a gate and a drain both connected to the bias signal PB; a transistor 242 which has a source connected to the power supply, a gate connected to the bias signal PB, and a drain connected to the bias signal NB; a transistor 243 which has a source connected to the ground, a gate connected to the control voltage Vcntl, and a drain connected to the bias signal PB; and a transistor 244 which has a source connected to the ground, and a gate and a drain both connected to the bias signal NB.

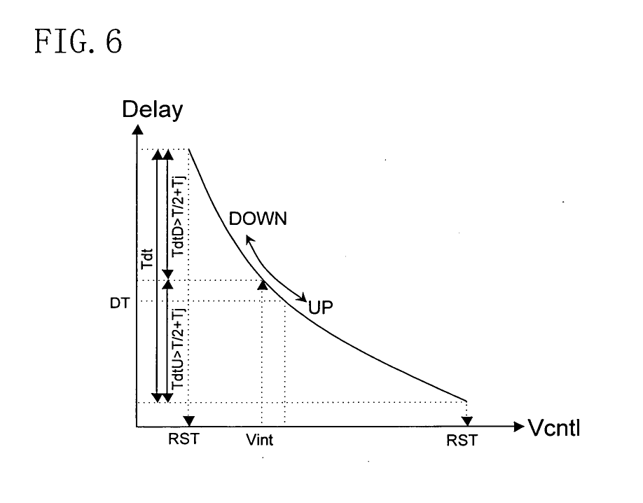

FIG. 6 illustrates a relationship between the control voltage Vcntl, and the delay amount DT (Delay) of the variable delay line 200 in the skew correction apparatus of FIG. 1. In the skew correction apparatus of this embodiment, as an initial setting, the control voltage Vcntl is set to be an initial value Vint so that phase comparison is started in a state that the clock signal CLK is delayed by a delay amount which is intermediate within a variable range (total variable range) Tdt of the delay amount DT of the variable delay line 200. In this case (i.e., at the start of phase comparison), a skew can be reliably corrected by setting the initial value Vint so that the variable delay line 200 has a variable delay range of T/2 or more (T: the cycle of one clock) in each of a direction in which the delay amount is decreased and a direction in which the delay amount is increased. Also, in order to increase or decrease the delay amount DT, following jitter from the locked state, a variable delay range Tj which corresponds to an amount of jitter from the locked point is required. Therefore, in this embodiment, as an initial setting, the initial value Vint is set so that the variable delay line 200 has a variable delay range of T/2+Tj or more in each of the direction in which the delay amount is decreased and the direction in which the delay amount is increased, where an intermediate point of the variable range Tdt of the delay amount DT in the variable delay line 200 is used as a reference. Specifically, the intermediate point of the variable range Tdt is determined so that all relationships represented by TdtD>T/2+Tj, TdtU>T/2+Tj, and TdtD+TdtU≦Tdt are satisfied, where TdtD represents a variable delay range in the direction in which the delay amount is increased, and TdtU represents a variable delay range in which the delay amount is decreased.

Hereinafter, a method of setting the initial value Vint of the control voltage Vcntl in the skew correction apparatus of FIG. 1, and the like, will be described in detail.

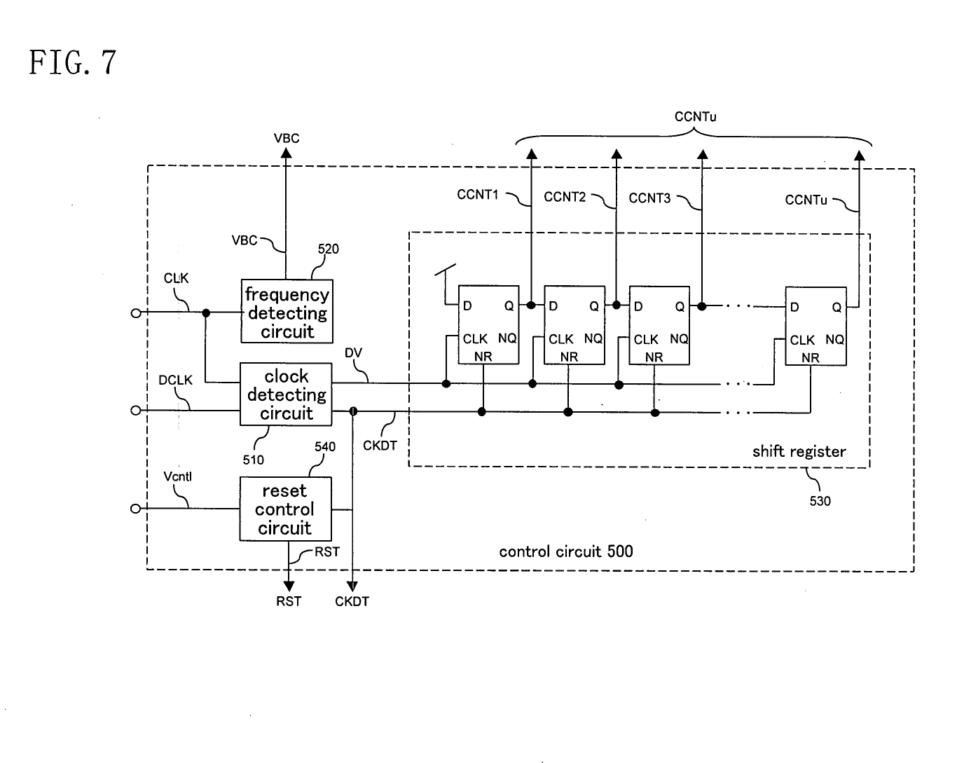

FIG. 7 illustrates an exemplary internal configuration of the control circuit 500 of FIG. 1. As illustrated in FIG. 7, the control circuit 500 is composed of: a clock detecting circuit 510 which detects the delayed clock signal DCLK from the variable delay line 200 and outputs a delayed clock detection signal CKDT indicating the detection; an u-stage shift register 530 which generates signals CCNTu (u is an integer) for controlling the charging means 40 which sets the initial value Vint during initial setting; a reset control circuit (reset signal generating circuit) 540 which generates a pulse signal RST for resetting the voltage holding means 6, depending on the control voltage Vcntl and the delayed clock detection signal CKDT; and a frequency detecting circuit 520 which detects a frequency of the clock signal CLK and, depending on the frequency, generates a signal VBC for changing the initial value Vint. Note that, in this embodiment, the delayed clock detection signal CKDT is at an L level in a state that the delayed clock signal DCLK is being output, and at an H level in a state that the delayed clock signal DCLK is not being output.

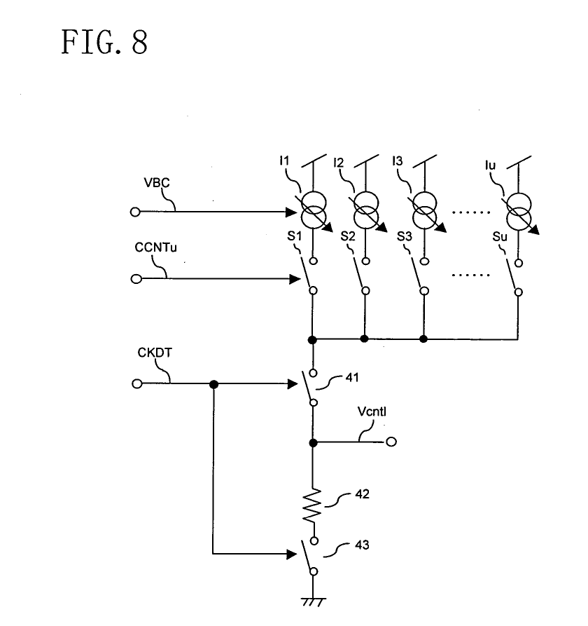

FIG. 8 illustrates an exemplary internal configuration of the charging means 40 of FIG. 1. As illustrated in FIG. 8, the charging means 40 is composed of: u current sources lu (u: an integer) which are arranged in parallel and adjust current amounts, depending on the signal VBC; u switches Su which are connected to the respective current sources lu and are turn ON/OFF by the respective signals CCNTu; a switch 41 which has one terminal connected to all of the switches Su and the other terminal connected to the control voltage Vcntl, and are turned ON/OFF by the delayed clock detection signal CKDT; a resistance 42 connected to the control voltage Vcntl; and a switch 43 which is connected between the resistance 42 and the ground, and is turned ON/OFF by the delayed clock detection signal CKDT. In this embodiment, the switch 41 and the switch 43 are ON in the state that the delayed clock signal DCLK is not being output, i.e., when the delayed clock detection signal CKDT is at the H level, and OFF in the state that the delayed clock signal DCLK is being output, i.e., when the delayed clock detection signal CKDT is at the L level.

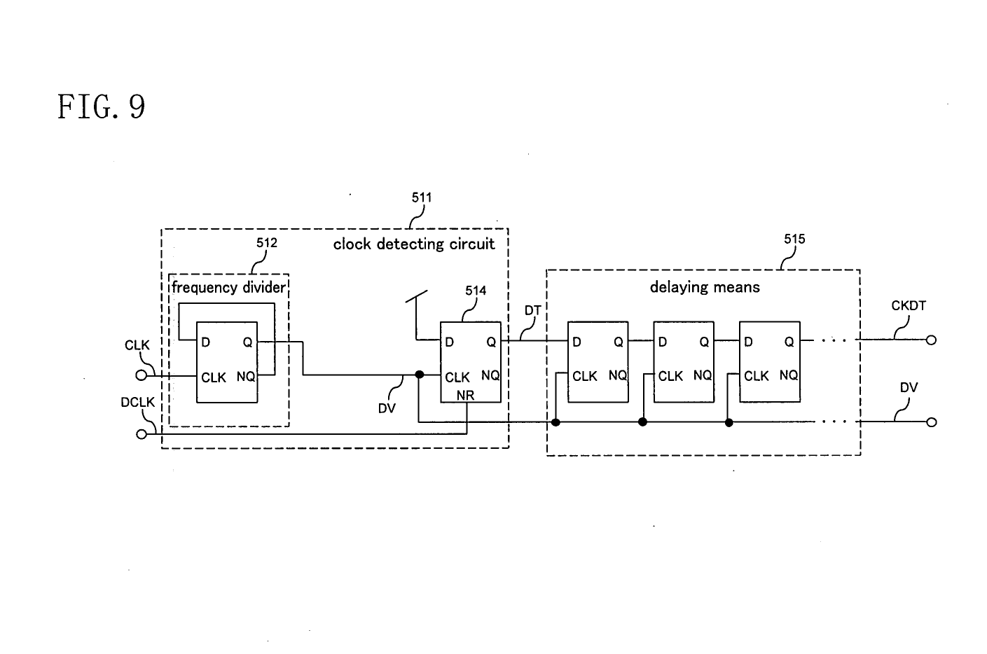

FIG. 9 illustrates an exemplary internal configuration of the clock detecting circuit 510 of FIG. 7. As illustrated in FIG. 9, the clock detecting circuit 510 is composed of a clock detecting circuit 511 and a delaying means 515. The clock detecting circuit 511 is composed of a frequency divider 512 which generates a clock signal DV (cycle T2) by frequency-dividing the clock signal CLK, and a D latch 514 which has a CLK input terminal through which the clock signal DV frequency-divided by the frequency divider 512 is input, a D input terminal which is fixed to an H level, and a Q output terminal through which a clock detection signal DT is output. Note that the delayed clock signal DCLK is input to an NR terminal of the D latch 514. The delaying means 515 is composed of an m-stage (m is an integer) shift register, and outputs a clock detection signal CKDT which is obtained by delaying the clock detection signal DT of the clock detecting circuit 511 by m frequency-divided clocks (m times the cycle T2 of the frequency-divided clock signal DV). In the D latch 514, in a state that the frequency-divided clock signal DV is input and the delayed clock signal DCLK is not input, the H level being input to the D input is invariably output as the clock detection signal DT through the Q output by a rising edge of the frequency-divided clock signal DV. When the delayed clock signal DCLK is started to be output from the variable delay line 200, the D latch 514 is reset by the delayed clock signal DCLK, so that an output level of the clock detection signal DT goes to an L level. Here, since the delayed clock signal DCLK has a cycle shorter than that of the frequency-divided clock signal DV, when the delayed clock signal DCLK is being output, the frequency of reset becomes higher, the L level is invariably output as the clock detection signal DT.

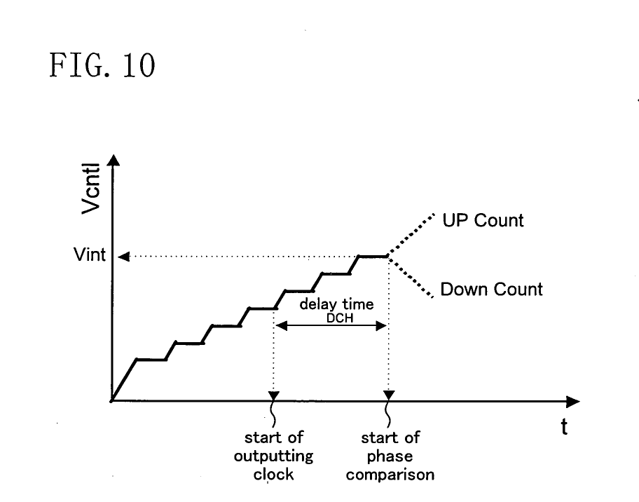

Next, initial setting performed in the control circuit (the control circuit 500) of FIG. 7 will be described. FIG. 10 illustrates an example of initial setting of the skew correction apparatus of FIG. 1. When the control voltage Vcntl is reset, the delayed clock signal DCLK is not being output from the variable delay line 200. In the shift register 530 of the control circuit 500 of FIG. 7, the signals CCNTu are changed from an L level to an H level successively from the signal CCNT1 by a rising edge of the frequency-divided clock signal DV. Meanwhile, the switches Su in the charging means 40 of FIG. 8 are turned ON successively from the switch S1, so that a current is input to the voltage holding means 6, whereby the control voltage Vcntl is increased as illustrated in FIG. 10. The clock detection signal CKDT is changed from the H level to the L level after being delayed by a delay DCH (=m×T2) corresponding to m clocks by the delaying means 515 of the clock detecting circuit 510 from a time when the delayed clock signal DCLK is started to be output due to an increase in the control voltage Vcntl. During this delay DCH, as illustrated in FIG. 10, the control voltage Vcntl is further increased to reach the initial value Vint which corresponds to an intermediate value of the variable delay range of the variable delay line 200. Also, when the clock detection signal CKDT is output, the switch 41 and the switch 43 in the charging means 40 are turned OFF, the charging means 40 is disconnected from the voltage holding means 6 and the initial value Vint is determined, whereby the initial setting is ended, and at the same time, the phase comparator 10 receives the clock detection signal CKDT and phase comparison is started.

As described above, during initial setting, the control circuit 500 controls the charging means 40 so that the voltage of the voltage holding means 6 is increased in a stepwise manner in units of a predetermined voltage, and the initial value Vint is determined by repeatedly applying the predetermined voltage to the voltage holding means 6 the number of times corresponding to a predetermined number of stages from a stage at which the clock detection signal CKDT has been output after confirming the output of the clock detection signal CKDT for each stage.

Here, the reason why the delay DCH is provided from the output of the delayed clock signal DCLK until the phase comparison is started is that, as described above, the initial value Vint is set so that the variable delay line 200 has a variable delay range of T/2+Tj or more in each of the direction in which the delay amount is decreased and the direction in which the delay amount is increased, and at the same time, and an influence of a group delay occurring from when the control voltage Vcntl is applied to the variable delay line 200 until when the delayed clock signal DCLK becomes stable, is eliminated. Also, as illustrated in FIG. 1, the phase comparator 10 outputs the UP signal or the DOWN signal to the charging/discharging means 30, depending on a difference in phase between the data signal DAT and the delayed clock signal DCLK. In this case, when the UP signal is output, the charging/discharging means 30 charges the voltage holding means 6, whereby the control voltage Vcntl is increased (UP Count). On the other hand, when the Down signal is output, the charging/discharging means 30 discharges the voltage holding means 6, whereby the control voltage Vcntl is decreased (Down Count).

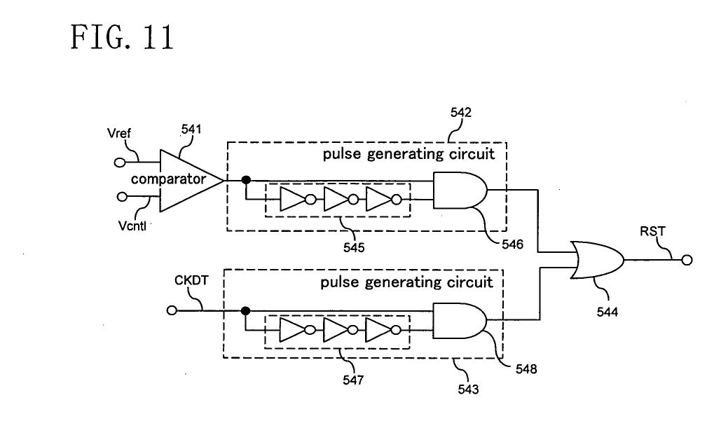

FIG. 11 illustrates an exemplary internal configuration of the reset signal generating circuit 540 of FIG. 7. As illustrated in FIG. 11, the reset signal generating circuit 540 is composed of: a comparator 541 which compares the control voltage Vcntl with a predetermined voltage Vref, and when Vcntl exceeds Vref, inverts an output thereof from an L level to an H level; a pulse generating circuit 542 connected to the comparator 541; a pulse generating circuit 543 connected to the clock detection signal CKDT; an OR gate 544 connected to the pulse generating circuit 542 and the pulse generating circuit 543. The pulse generating circuit 542 is composed of an inverter chain 545 having an odd number of stages and slave-connected to the comparator 541, and an AND gate 546 connected to the comparator 541 and the inverter chain 545. The pulse generating circuit 543 has the same configuration as that of the pulse generating circuit 542, and specifically, is composed of an inverter chain 547 having an odd number of stages and slave-connected to the clock detection signal CKDT, and an AND gate 548 connected to the clock detection signal CKDT and the inverter chain 547. As described above, when Vcntl becomes larger than Vref, the output of the comparator 541 is inverted from the L level to the H level. The pulse generating circuit 542 detects the transition from the L level to the H level and generates a pulse, and the pulse is output as an RST signal through the OR gate 544. Also, the output of the delayed clock signal DCLK from the variable delay line 200 is stopped, the clock detection signal CKDT goes from the L level to the H level. The pulse generating circuit 543 detects the transition and generates a pulse, and the pulse is output as the RST signal through the OR gate 544. With such a configuration of the reset signal generating circuit 540, as illustrated in FIG. 6, when Vcntl is excessively high so that the delay amount of the variable delay line 200 reaches the upper limit of the variable range and when Vcntl is excessively low so that the output of the delayed clock signal DCLK is stopped, the reset signal RST is output. When the reset signal RST is output, the voltage holding means 6 is reset by turning ON the switch 7 of FIG. 1, so that initial setting and thereafter are performed again, thereby making it possible to prevent reception of erroneous data.

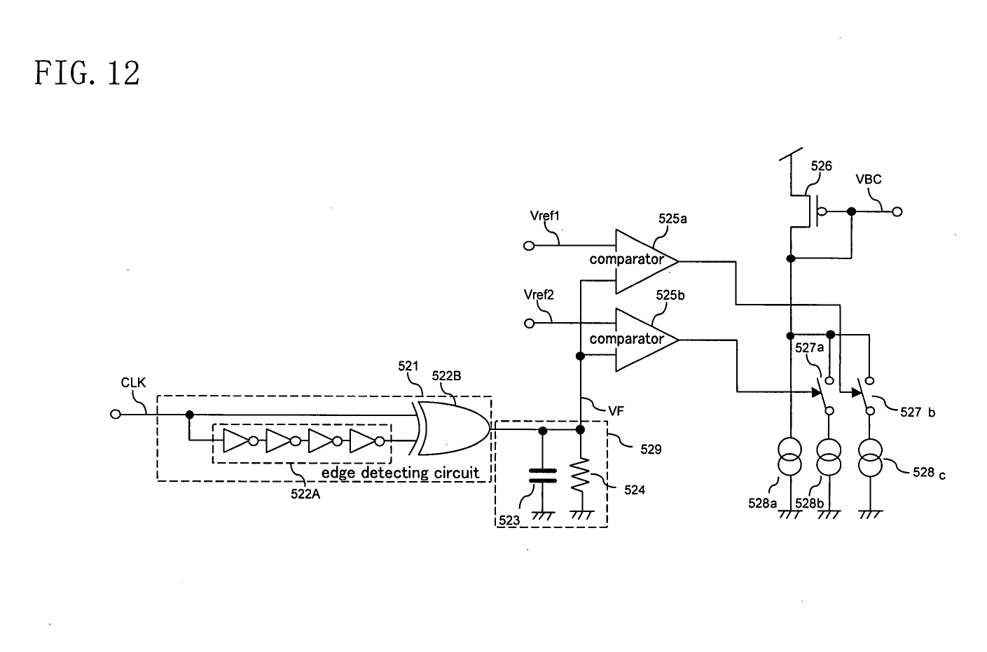

FIG. 12 illustrates an exemplary internal configuration of the frequency detecting circuit 520 of FIG. 7. As illustrated in FIG. 12, the frequency detecting circuit 520 is composed of: a pulse generating circuit 521 which detects an edge of the clock signal CLK and outputs a pulse; an integrator 529 composed of a capacitance 523 and a resistance 524; a comparator 525a which compares a result VF of integration by the integrator 529 with a predetermined voltage Vref1; a comparator 525b which compares the integration result VF of the integrator 529 with a predetermined voltage Vref2 which is set to be lower than the predetermined voltage Vref1; a transistor 526 which has a drain and a gate both connected to the signal VBC and a source connected to the power supply; a current source (transformer) 528a connected between the signal VBC and the ground; a switch 527b which is connected to the signal VBC and is turned ON/OFF, depending on a comparison result of the comparator 525a; a current source (transformer) 528c connected between the switch 527b and the ground; a switch 527a which is connected to the signal VBC and is turned ON/OFF, depending on a comparison result of the comparator 525b; and a current source 528b connected between the switch 527a and the ground. Also, the pulse generating circuit 521 is composed of an inverter chain 522A having an even number of stages and slave-connected to the clock signal CLK, and an EXOR gate 522B connected to the clock signal CLK and the inverter chain 522A. The pulse generating circuit 521 detects each of a rising edge and a falling edge of the clock signal CLK and generates a pulse. The pulse is integrated by the integrator 529, and therefore, the more the number of high-frequency pulses occurring within a unit time, the higher the voltage of the integration result VF of the integrator 529. In the frequency detecting circuit 520, the integration result VF is compared with each of the predetermined voltage Vref2, and the predetermined voltage Vref1 which is higher than Vref2, and depending on results of the comparison, the amount of a current which is caused to flow through the transistor 526 is adjusted, thereby making it possible to change the bias signal VBC, depending on a frequency of the clock signal CLK. Thereby, the charging means 40 can be controlled so that a magnitude of the initial value Vint of the control voltage Vcntl is changed, depending on the frequency of the clock signal CLK.

As described above, according to this embodiment, the phase comparison operation is started from an intermediate point within the variable range of the delay amount of the variable delay line 200, thereby making it possible to perform conventional skew correction no matter whether a phase is delayed or advanced, and perform an operation, following fluctuation due to jitter. Also, when the delay amount of the variable delay line 200 reaches the upper or lower limit of the variable range, resetting is performed and initial setting and thereafter are performed again, thereby making it possible to prevent reception of erroneous data. Therefore, it is possible to achieve a skew correction apparatus capable of achieving data reception highly resistant to jitter.

Although the delay line 210 having a plurality of stages of the delay cells UDk is employed in the variable delay line 200 of this embodiment, a single-type delay line may be employed instead of this.

Also, in the variable delay line 200 of this embodiment, the bias generating circuit 240 may have any configuration as long as a bias signal for a delay cell is generated by the control voltage Vcntl.

Also, in the clock detecting circuit 510 of the control circuit 500 of this embodiment, the ½ frequency divider 512 is used, though a frequency divider having any division ratio can be used as the frequency divider 512. Also, the clock detecting circuit 510 may have any configuration as long as it has a function of detecting a clock signal.

Also, in this embodiment, the charging means 40 has a configuration in which the voltage of the voltage holding means 6 is changed in a stepwise manner. Instead of this, the charging means 40 may have a configuration in which the voltage holding means 6 is set to be a predetermined voltage in one charging operation. Specifically, during initial setting, the control circuit 500 may set the voltage Vcntl of the voltage holding means 6 to be a predetermined voltage in one charging operation by the charging means 40. Alternatively, the charging means 40 may have a configuration in which a constant current is caused to flow into the voltage holding means 6. Specifically, the control circuit 500 may control the charging means 40 during initial setting so that the initial value of the voltage Vcntl of the voltage holding means 6 is determined under conditions that the voltage of the voltage holding means 6 is increased at a constant increasing rate and the clock detection signal CKDT is being output. In this case, the control circuit 500 may control the charging means 40 so that the initial value of the voltage Vcntl is determined by further applying a predetermined voltage to the voltage holding means 6 after the clock detection signal CKDT is output. As described above, as long as the initial value Vint of the control voltage Vcntl can be set during initial setting so that the variable delay line 200 has a variable delay range of T/2+Tj or more in each of the direction in which the delay amount is decreased and the direction in which the delay amount is increased, the configuration of the charging means 40 is not particularly limited.

Also, in this embodiment, the control circuit 500 starts the phase comparison operation at the same time as when the above-described initial setting is ended. Instead of this, the phase comparison operation may be started a predetermined time after the end of the initial setting.

Also, in reset signal generating circuit 540 of the control circuit 500 of this embodiment, when Vcntl is excessively low, the voltage holding means 6 is reset by detecting the stop of output of the delayed clock signal DCLK. However, instead of this, as is similar to when Vcntl is excessively high, the voltage holding means 6 may be reset by detecting that the delay amount of the variable delay line 200 reaches the lower limit of the variable range, using a method of using a comparator, or the like.

Also, although two comparators are employed in the frequency detecting circuit 520 of the control circuit 500 of this embodiment, the number of comparators is not particularly limited.

Also, in this embodiment, the clock signal CLK is delayed by the variable delay line 200. Instead of this, the data signal DAT may be delayed by the variable delay line, and in this case, a similar effect is obtained. Specifically, in the skew correction apparatus of this embodiment of FIG. 1, a variable delay line for generating a delayed data signal by delaying the data signal DAT by a variable delay amount may be provided instead of the variable delay line 200 for generating the delayed clock signal DCLK by delaying the clock signal CLK by the variable delay amount DT, and a phase comparator for comparing the transition of the delayed data signal with the phase of the clock signal CLK may be provided instead of the phase comparator 10 for comparing the phase of the delayed clock signal DCLK with the transition of rising of the data signal DAT.

### INDUSTRIAL APPLICABILITY

The present invention relates to a skew correction apparatus for correcting a skew of a data signal with respect to a clock signal, and provides a significant effect that a high level of jitter resistance is exhibited, so that accurate data reception can be achieved, when applied to high-speed data communication.

1. A skew correction apparatus for correcting a skew of a data signal with respect to a clock signal, comprising:
a variable delay line for generating a delayed clock signal by delaying the clock signal by a variable delay amount;
a phase comparator for comparing transition of the data signal with a phase of the delayed clock signal;
a voltage holding means for adjusting a delay amount of the variable delay line, depending on a held voltage;
a charging/discharging means for changing the voltage of the voltage holding means, depending on a comparison result of the phase comparator;
a charging means for setting an initial value of the voltage of the voltage holding means at start of a phase comparison operation, as an initial setting; and
a control circuit for controlling the charging means so that a phase comparison operation is started in a state that the variable delay line delays the clock signal by a delay amount which is intermediate within a delay adjustable range, to determine the initial value as the initial setting.

2. The skew correction apparatus of claim 1, wherein, at start of phase comparison, the variable delay line has a variable delay range of half of a clock cycle or more in each of a direction in which a delay amount is decreased and a direction in which a delay amount is increased.

3. The skew correction apparatus of claim 2, wherein the control circuit comprises a clock detector for detecting transition of output of the variable delay line and outputting a clock detection signal indicating the transition, and causes a phase comparison operation to start under a condition that the clock detector has detected the transition.

4. The skew correction apparatus of claim 3, wherein, during the initial setting, the control circuit sets the voltage of the voltage holding means to be a predetermined voltage in one charging operation by the charging means.

5. The skew correction apparatus of claim 3, wherein, during the initial setting, the control circuit controls the charging means so that the initial value is determined under conditions that the voltage of the voltage holding means is increased at a constant increasing rate and the clock detection signal is being output.

6. The skew correction apparatus of claim 5, wherein the control circuit controls the charging means so that the initial value is determined by further applying a predetermined voltage to the voltage holding means after the clock detection signal is output.

7. The skew correction apparatus of claim 3, wherein, during the initial setting, the control circuit controls the charging means so that the voltage of the voltage holding means is increased in a stepwise manner in units of a predetermined voltage, and the initial value is determined by repeatedly applying the predetermined voltage to the voltage holding means the number of times corresponding to a predetermined number of stages from a stage at which the clock detection signal has been output after confirming output of the clock detection signal for each stage.

8. The skew correction apparatus of claim 3, wherein, when the output of the clock detection signal from the clock detector is stopped, the control circuit resets the voltage holding means and performs the initial setting and thereafter again.

9. The skew correction apparatus of claim 2, wherein the control circuit starts a phase comparison operation a predetermined time after end of the initial setting.

10. The skew correction apparatus of claim 2, wherein the control circuit, when the delay amount of the variable delay line reaches an upper limit of the variable range, resets the voltage holding means and performs the initial setting and thereafter again.

11. The skew correction apparatus of claim 2, wherein the control circuit, when the delay amount of the variable delay line reaches a lower limit of the variable range, resets the voltage holding means and performs the initial setting and thereafter again.

12. The skew correction apparatus of claim 2, wherein the control circuit controls the charging means so that the initial value is changed, depending on a frequency of the clock signal.

13. The skew correction apparatus of claim 12, wherein the control circuit comprises a frequency detecting circuit for detecting the frequency of the clock signal, and depending on a detection result of the frequency detecting circuit, controls the charging means so that the initial value is changed.

14. A skew correction apparatus for correcting a skew of a data signal with respect to a clock signal, comprising:
a variable delay line for generating a delayed data signal by delaying the data signal by a variable delay amount;
a phase comparator for comparing transition of the delayed data signal with a phase of the clock signal;
a voltage holding means for adjusting a delay amount of the variable delay line, depending on a held voltage;
a charging/discharging means for changing the voltage of the voltage holding means, depending on a comparison result of the phase comparator;
a charging means for setting an initial value of the voltage of the voltage holding means at start of a phase comparison operation, as an initial setting; and
a control circuit for controlling the charging means so that a phase comparison operation is started in a state that the variable delay line delays the data signal by a delay amount which is intermediate within a delay adjustable range, to determine the initial value as the initial setting.

15. The skew correction apparatus of claim 14, wherein, at start of phase comparison, the variable delay line has a variable delay range of half of a clock cycle or more in each of a direction in which a delay amount is decreased and a direction in which a delay amount is increased.

16. The skew correction apparatus of claim 15, wherein the control circuit comprises a clock detector for detecting transition of output of the variable delay line and outputting a clock detection signal indicating the transition, and causes a phase comparison operation to start under a condition that the clock detector has detected the transition.

17. The skew correction apparatus of claim 16, wherein, during the initial setting, the control circuit sets the voltage of the voltage holding means to be a predetermined voltage in one charging operation by the charging means.

18. The skew correction apparatus of claim 16, wherein, during the initial setting, the control circuit controls the charging means so that the initial value is determined under conditions that the voltage of the voltage holding means is increased at a constant increasing rate and the clock detection signal is being output.

19. The skew correction apparatus of claim 18, wherein the control circuit controls the charging means so that the initial value is determined by further applying a predetermined voltage to the voltage holding means after the clock detection signal is output.

20. The skew correction apparatus of claim 16, wherein, during the initial setting, the control circuit controls the charging means so that the voltage of the voltage holding means is increased in a stepwise manner in units of a predetermined voltage, and the initial value is determined by repeatedly applying the predetermined voltage to the voltage holding means the number of times corresponding to a predetermined number of stages from a stage at which the clock detection signal has been output after confirming output of the clock detection signal for each stage.

21. The skew correction apparatus of claim 16, wherein, when the output of the clock detection signal from the clock detector is stopped, the control circuit resets the voltage holding means and performs the initial setting and thereafter again.

22. The skew correction apparatus of claim 15, wherein the control circuit starts a phase comparison operation a predetermined time after end of the initial setting.

23. The skew correction apparatus of claim 15, wherein the control circuit, when the delay amount of the variable delay line reaches an upper limit of the variable range, resets the voltage holding means and performs the initial setting and thereafter again.

24. The skew correction apparatus of claim 15, wherein the control circuit, when the delay amount of the variable delay line reaches a lower limit of the variable range, resets the voltage holding means and performs the initial setting and thereafter again.

25. The skew correction apparatus of claim 15, wherein the control circuit controls the charging means so that the initial value is changed, depending on a frequency of the clock signal.

26. The skew correction apparatus of claim 25, wherein the control circuit comprises a frequency detecting circuit for detecting the frequency of the clock signal, and depending on a detection result of the frequency detecting circuit, controls the charging means so that the initial value is changed.
